(19) United States
(12) Patent Application Publication
(10) Pub. No.: US 2007/0091944 A1
(43) Pub. Date: Apr. 26, 2007

(54) Widely tunable RF source

(76) Inventor: Everardo Ruiz, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/241,426

(22) Filed: Sep. 30, 2005

(51) Int. Cl. H01S 5/00; H01S 3/10; H01S 3/04

(52) U.S. Cl. 372/22; 372/43.01

(57) ABSTRACT

A detector is optically coupled to a first and a second semiconductor laser, wherein the detector to output two or more beat frequencies generated by mixing optical outputs of the first and second semiconductor lasers, wherein the two or more beat frequencies are electrical signals.

### TECHNICAL FIELD

Embodiments of the invention relate to the field of radios and more specifically, but not exclusively, to a widely tunable radio frequency (RF) source.

### BACKGROUND

Modern electronic devices may transmit on a variety of radio frequencies. For example, cellular phones may transmit at approximately 900 Megahertz (MHz), a wireless local area network (WLAN), such as a Wireless Fidelity (WiFi) network, may operate in the 2.4-5.0 Gigahertz (GHz) frequency range (see, for example, Institute of Electrical and Electronics Engineers (IEEE) 802.11 standard published in 1999), and WiMAX capable devices may operate in the 3-11 GHz frequency range (see, for example, IEEE 802.16 standard published December 2001). In today's designs, a wireless device may include multiple Voltage Controlled Oscillators (VCOs) to operate in multiple bands.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram illustrating a widely tunable RF source in accordance with an embodiment of the present invention.

FIG. 2 is a flowchart illustrating the logic and operations of a widely tunable RF source in accordance with an embodiment of the present invention.

FIG. 3 is a block diagram illustrating a package having two semiconductor lasers for use in a widely tunable RF source in accordance with an embodiment of the present invention.

FIG. 4 is a block diagram illustrating a system having a widely tunable RF source in accordance with an embodiment of the present invention.

FIG. 5 is a block diagram illustrating a system having a widely tunable RF source in accordance with an embodiment of the present invention.

### DETAILED DESCRIPTION

In the following description, numerous specific details are set forth to provide a thorough understanding of embodiments of the invention. One skilled in the relevant art will recognize, however, that embodiments of the invention can be practiced without one or more of the specific details, or with other methods, components, materials, etc. In other instances, well-known structures, materials, or operations are not shown or described in detail to avoid obscuring understanding of this description.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the following description and claims, the term “coupled” and its derivatives may be used. “Coupled” may mean that two or more elements are in direct contact (physically, electrically, magnetically, optically, etc.). “Coupled” may also mean two or more elements are not in direct contact with each other, but still cooperate or interact with each other.

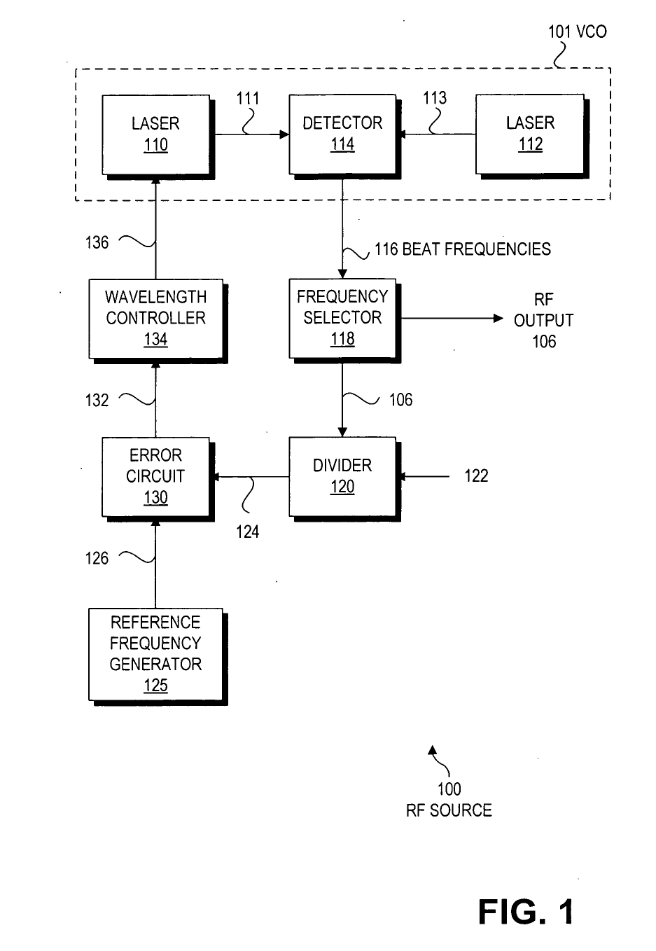

Referring to FIG. 1, an embodiment of an RF source 100 is shown. RF source 100 may also be referred to as a synthesizer. As will be described below, RF source 100 may include two semiconductor lasers that produce a beat frequency output through optical heterodyning. The high output frequency of the semiconductor lasers enables the ability to tune RF source 100 across a wide range of frequencies. In one embodiment, RF source 100 may be tuned between 0 and 100 GHz. Thus, a single VCO design may provide an RF source for a wide variety of frequency bands.

RF source 100 includes a semiconductor laser 110 and a semiconductor laser 112. Embodiments of semiconductor lasers 110 and 112 include a Vertical Cavity Surface Emitting Laser (VCSEL), a Fabry-Perot (FP) laser, a Distributed-Feedback (DFB) laser, or the like.

Optical outputs 111 and 113 of lasers 110 and 112, respectively, are directed to a detector 114. In one embodiment, detector 114 includes a non-linear optical-to-electrical element, such as a photodetector. Embodiments of a photodetector include a photodiode, such as a PIN (positive intrinsic negative) diode. Detector 114 outputs beat frequencies 116 generated by the optical heterodyning effect of optical outputs 111 and 113. Beat frequencies 116 are electrical signals.

Optical heterodyning involves mixing two (or more) signals in a non-linear device to generate beat frequencies. This mixing may also be referred to as “beating” the signals. The beat frequencies include at least two new frequencies, one at the sum of the two original signals and another at the difference of the two original signals. For example, if a 1 GHz signal and a 990 MHz signal are “beat,” the resulting difference is 10 MHz. The term “beat” originates from the fact that when two acoustic signals of slight different frequency are mixed, a beating sound is heard.

The beat frequencies 116 are passed through frequency selector 118. In one embodiment, frequency selector 118 includes a low-pass filter. Embodiments of frequency selector 118 also include an Inductor-Capacitor (L-C) circuit, a distributed transmission line, a Microelectromechanical System (MEMS) device, or the like.

Frequency selector 118 selects the beat frequency from beat frequencies 116 to be output as RF output 106. In one embodiment, the lowest beat frequency is the selected frequency. In another embodiment, at least one of beat frequencies 116 is between approximately 0 and 100 Gigahertz. RF output 106 is used as a local oscillator in a radio or as the radio system carrier frequency.

RF output 106 is also sent to a divider 120 (also referred to as a pre-scaler) from frequency selector 118. Divider 120 divides down RF output 106 by a divide factor that has been loaded into divider 120. The divided down RF output 124 is compared at an error circuit 130 to a reference signal 126. Embodiments of error circuit 130 include a comparator, a digital comparator, or the like. Reference signal 126 may be generated by a reference frequency generator 125. An error signal 132 is output by error circuit 130 and input into a wavelength controller 134.

Wavelength controller 134 sends a control signal 136 to laser 110 for tuning laser 110 in response to error signal 132. In one embodiment, laser 110 is tuned through temperature control. In other embodiments, laser 110 may be tuned mechanically, electrically by adjusting the injected current, acoustically, or the like.

It will be appreciated by one skilled in the art having the benefit of this disclosure that RF source 100 operates like phase-locked-loop (PLL) synthesizer. The control loop continually corrects the wavelength of laser 110 as needed to maintain RF output 106 to a selected frequency.

To tune RF output 106 to a new frequency, a new divide factor is loaded into divider 120 using a divider control signal 122. When the divided down frequency 124 matches reference frequency 126, the RF source stabilizes at the new frequency. Thus, the same control loop used to maintain RF output 106 at a desired frequency may also be used to tune the RF output 106 to a new frequency.

Embodiments of the present invention provide an RF source up to 100 Gigahertz using a single VCO. In one embodiment, a VCO 101 of RF source 100 includes semiconductor lasers 110 and 112 and detector 114 that perform the optical heterodyning. A small difference in wavelength of the lasers results in a large change in the beat frequency. Thus, very little wavelength change is needed to produce a wide range of outputted RF frequencies.

For example, lasers 110 and 112 may be tunable in the optical communications C-band (approximately 1530 to 1565 nanometers (nm)). 1530 nm equates to approximately 195.943 Terahertz (THz) while 1530.5 nm equates to approximately 195.879 THz. Thus, heterodyning the two signals produces a beat frequency of 0.064 THz which is 64 GHz. Thus, a very slight change in wavelength of one of the lasers produces a large RF frequency tuning range.

In one embodiment, lasers 110 and 112 are fabricated on separate dies and placed in the same package. In another embodiment, lasers 110 and 112 are fabricated on the same die and packaged in the same package. Such a package may be mounted to the same substrate or board as the other components of RF source 100. In an alternative embodiment, the other components of RF source 100 may be integrated underneath a die having the two lasers.

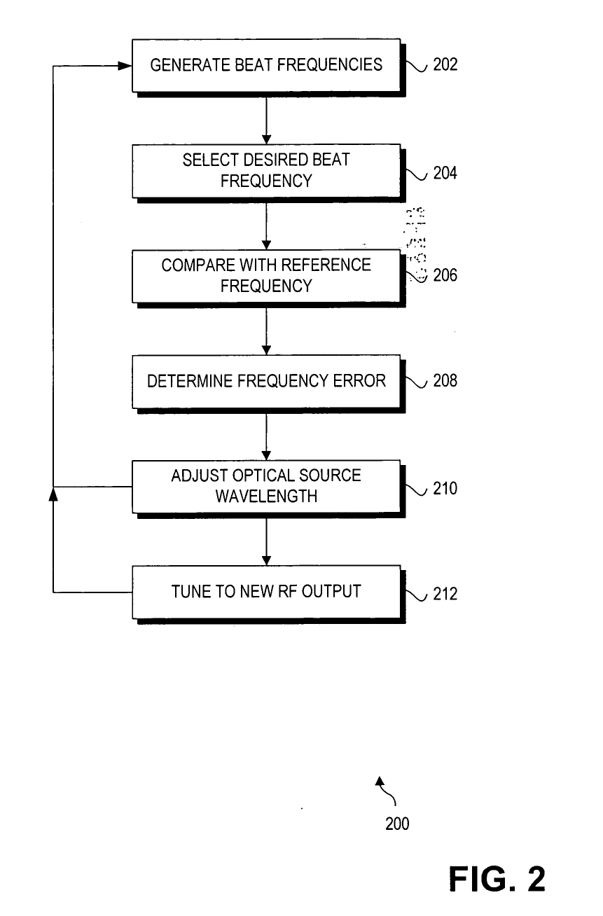

Turning to FIG. 2, a flowchart 200 shows the logic and operations of an embodiment of the invention. In one embodiment, the logic and operations of flowchart 200 may be implemented using RF source 100.

Starting in a block 202, beat frequencies are generated from two or more optical sources using optical heterodyning. Continuing to a block 204, the desired beat frequency is selected from the beat frequencies and output from the RF source as an RF output. In a block 206, the selected beat frequency is compared to a reference frequency.

Proceeding to a block 208, a frequency error of the RF output is determined as the difference between the selected beat frequency and the reference frequency. Continuing to a block 210, the wavelength of one of the optical sources is adjusted based on the frequency error.

In one embodiment, the wavelength is adjusted by temperature control, such as by changing the current applied to a resistive metal strip proximate to the semiconductor laser; in another embodiment, the current injected into the laser is adjusted. In yet another embodiment, the wavelength may be adjusted by a combination of temperature control and current control. For example, temperature control may be used for course tuning and current control may be used for fine turning (or vice-versa).

After block 210, the logic then continues back to block 202 to continue to generate the beat frequencies. It will be appreciated that the logic of blocks 202-210 form a control loop for maintaining the RF output at a selected frequency.

In a block 212, the RF output is tuned to a new frequency. In one embodiment, divider 120 is loaded with a new divide factor to tune RF source 100 to a new frequency. After block 212, the logic returns to block 202 to stabilize the RF source at the new RF frequency using the control loop of blocks 202-210.

Embodiments herein provide an RF source having a fast settling time in combination with low phase noise. In conventional VCOs, a faster settling time is balanced against higher phase noise of the RF output. Settling time is an important industry parameter which describes the time required to switch between RF frequencies (usually between RF carrier frequency channels). RF frequencies generated by beating laser sources together provide lower phase noise as compared to electrical signal sources. Thus, embodiments described herein provide fast settling time simultaneously with low phase noise measured in very low dBc/Hz (decibel-carrier/hertz). Decibel-carrier/hertz describes the decibels below the carrier peak normalized to measurement bandwidth at a given frequency offset from the carrier frequency.

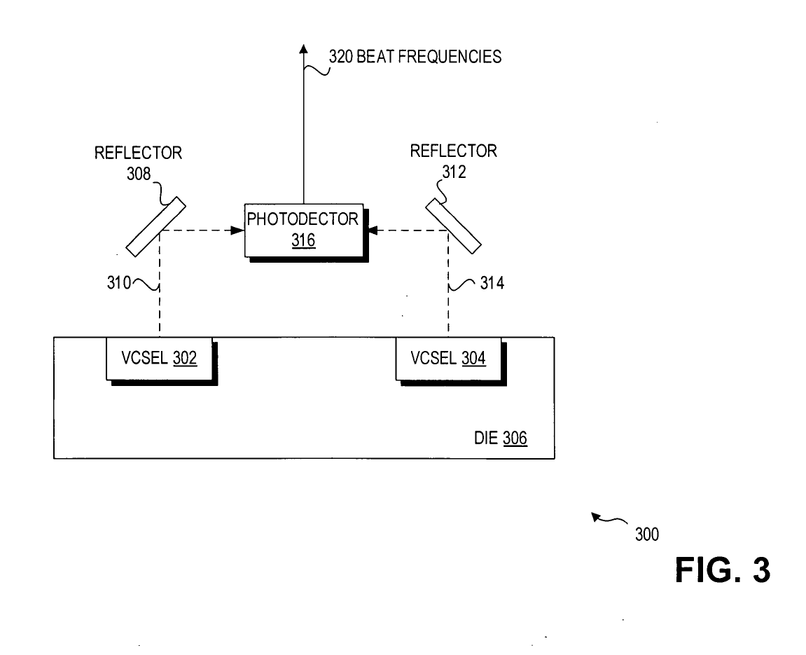

Turning to FIG. 3, an embodiment of a package 300 having two semiconductor lasers integrated on the same die is shown. Package 300 includes VCSEL 302 and 304 integrated on the same die 306. Package 300 may also include a photodetector 316. Optical outputs 310 and 314 of VCSELs 302 and 304, respectively, may be directed to photodetector 316 for optical heterodyning. Optical outputs 310 and 314 “beat” against each other at photodetector 316 to generate beat frequencies 320. Beat frequencies 320 are output as electrical signals. In one embodiment, VCO 101 may be implemented by package 300.

Package 300 may also include reflectors 308 and 312. Optical output 310 of VCSEL 302 is directed to photodetector 316 by reflector 308. Optical output 314 of VCSEL 304 is directed to photodetector 316 using reflector 312. It will be appreciated that embodiments of the invention include other configurations of reflectors, waveguides, or any combination thereof to direct optical outputs from VCSELs 302 and 304 to photodetector 316. In other embodiments, the optical outputs are sent directly to photodetector 316 without using reflectors.

In one embodiment, reflectors 308 and 312 are made from plastic. In one embodiment, such plastic reflectors are made from injection molded plastic.

Alternative embodiments of package 300 may include each VCSEL 302 and 304 fabricated on its own respective die and packaged together in package 300. VCSELs 302 and 304 may be mounted together on a substrate, such as a printed circuit board. In another embodiment, photodetector 316 may be outside of package 300. In this embodiment, optical outputs 310 and 314 may by directed to photodetector 316 by reflectors, waveguides, or the like, or any combination thereof.

Using semiconductor lasers, such as VCSELs 302 and 304, are advantageous for mobile wireless devices because they use small amounts of current and generate little heat. In one embodiment, each VCSEL consumes approximately 2 milliamperes of current. Also, embodiments of package 300 may have a small form factor. In one embodiment, package 300 may be less than 2 millimeters in height.

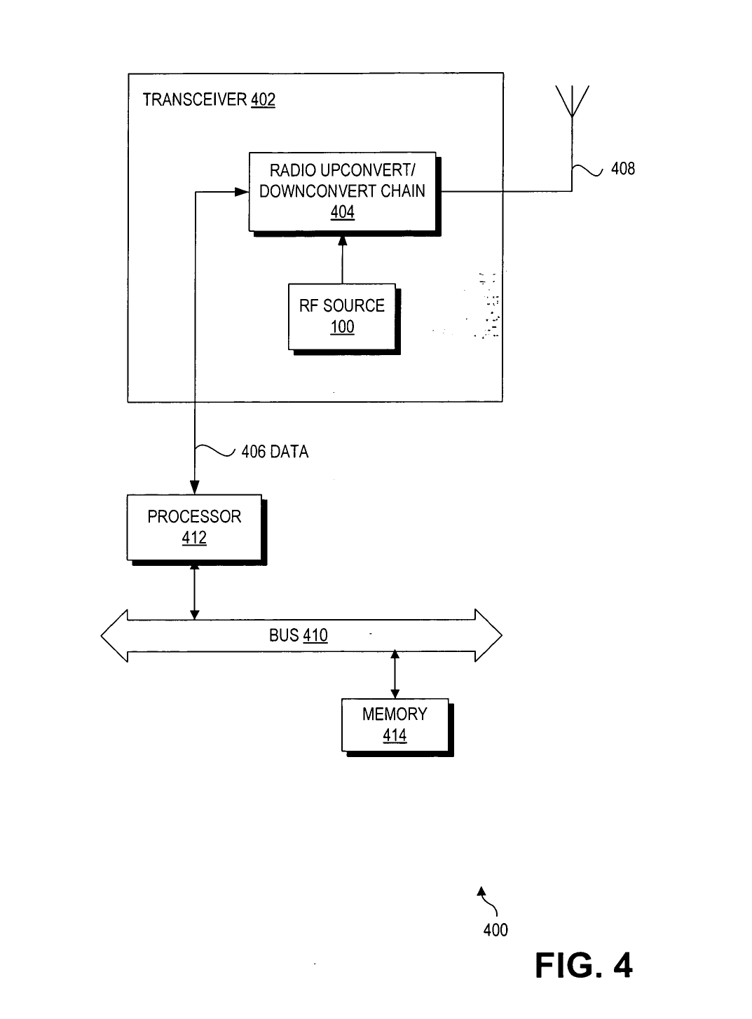

Referring to FIG. 4, an embodiment of a system 400 using direct conversion in accordance with an embodiment of the invention is shown. Transceiver 402 includes RF source 100 coupled to a radio upconvert/downconvert chain 404. Radio upconvert/downconvert chain 404 is coupled to an antenna 408.

Transceiver 402 is coupled to a processor 412 (also referred to as a baseband processor). Processor 412 is coupled to a bus 410. Other components, such as memory 414, may be coupled to bus 410. Data 406 is sent to radio upconvert/downconvert chain 404 when transmitting and received from radio upconvert/downconvert chain 404 when receiving. When transmitting, data 406 is impressed onto the RF output of RF source 100. When receiving, the RF output of RF source 100 is used in recovering data from a received signal.

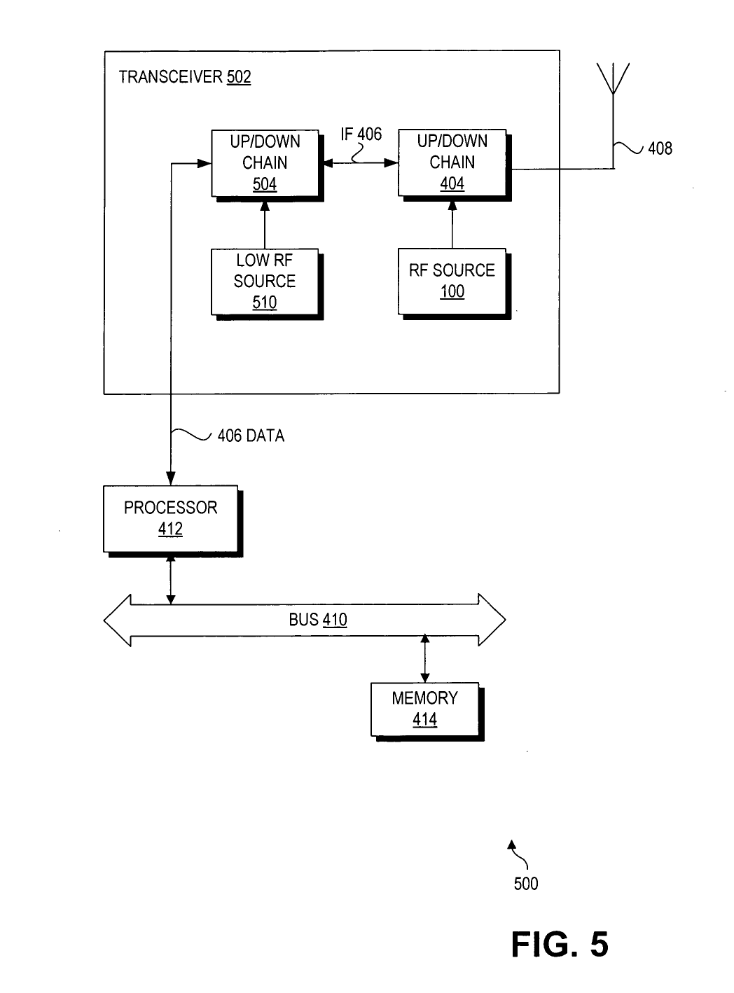

Referring to FIG. 5, an embodiment of a system 500 using dual conversion in accordance with an embodiment of the invention is shown. System 500 includes a transceiver 502 coupled to processor 412. Transceiver 502 includes a radio upconvert/downconvert chain (shown as “up/down chain”) 504 coupled to radio upconvert/downconvert chain 404. Radio upconvert/downconvert chain 504 receives a low RF source 510 to encode/decode data 406 on a low frequency signal, such as 10-500 MHz signal. Radio upconvert/downconvert chain 504 is coupled to radio upconvert/downconvert chain 404. An intermediate frequency (IF) 406 may pass between radio upconvert/downconvert chains 404 and 504. RF source 100 is coupled to radio upconvert/downconvert chain 404 to provide an RF output to upconvert/downconvert chain 404. When transmitting, the RF output of RF source 100 increases IF 406 to the desired transmit frequency. When receiving, the RF output of RF source 100 lowers the frequency of the received signal to IF 406.

In FIGS. 4 and 5, other components of transceivers 402 and 502, such as an amplifier, are not shown for the sake of clarity. It will also be appreciated that RF source 100 may be used in a separate transmitter or separate receiver and not necessarily in a transceiver. For example, an alternative embodiment of FIG. 4 includes a transmitter with a radio upconvert chain.

RF source 100 may be used in a wireless device. Embodiments of a wireless device include, but are not limited to, a laptop computer, a personal digital assistant, a pocket personal computer, a wireless phone, a medical device, or the like. RF source 100 may also be used in other devices such as a Network Interface Card (NIC), a Personal Computer Memory Card International Association (PCMCIA) card, or the like. An RF source as described herein may be used in other wireless devices, such as car radios and tracking systems, or the like.

Embodiments of the invention provide a widely tunable RF source having a single VCO. As wireless platforms evolve, multiband tuning capability is expected. These platforms may be expected to have radio capability such as WiMax operating at 3-66 GHz (see, for example, Institute of Electrical and Electronics Engineers (IEEE) 802.16 standard published December 2001), a wireless LAN operating between 2.4 to 5 GHz (see, for example, IEEE 802.11 standard published in 1999), cellular phones (800-900 MHz), Personal Communication Services (1.9 GHz), Ultra Wideband (UWB) radio, as well as Amplitude Modulation (AM) radio, Frequency Modulation (FM) radio, television, Global Positioning System (GPS), satellite radio, and so forth.

Instead of adding multiple narrow band RF oscillators to a single wireless device, embodiments described herein provide a single VCO for tuning across numerous RF bands. Embodiments of the single wideband RF source described herein address all of the above frequency bands in a single device. Using a single RF source lowers costs and provides a small form factor. Further, semiconductor lasers consume small amounts of current and produce little heat as compared to other types of VCOs. Additionally, manufacturing is simplified because a single RF source may be used in a variety of different devices instead of having to produce different RF sources for different devices having different operating frequency requirements.

Various operations of embodiments of the present invention are described herein. These operations may be implemented by a machine using a processor, an Application Specific Integrated Circuit (ASIC), a Field Programmable Gate Array (FPGA), or the like. In one embodiment, one or more of the operations described may constitute instructions stored on a machine-readable medium, that when executed by a machine will cause the machine to perform the operations described. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment of the invention.

The above description of illustrated embodiments of the invention, including what is described in the Abstract, is not intended to be exhaustive or to limit the embodiments to the precise forms disclosed. While specific embodiments of, and examples for, the invention are described herein for illustrative purposes, various equivalent modifications are possible, as those skilled in the relevant art will recognize. These modifications can be made to embodiments of the invention in light of the above detailed description. The terms used in the following claims should not be construed to limit the invention to the specific embodiments disclosed in the specification. Rather, the following claims are to be construed in accordance with established doctrines of claim interpretation.

What is claimed is:

1. An apparatus, comprising:
a first semiconductor laser and a second semiconductor laser; and
a detector optically coupled to the first and second semiconductor lasers, wherein the detector to output two or more beat frequencies generated by mixing optical outputs of the first and second semiconductor lasers, wherein the two or more beat frequencies are electrical signals.

2. The apparatus of claim 1, further comprising a frequency selector coupled to the detector to receive the two or more beat frequencies and to output a Radio Frequency (RF) output selected from the received the two or more beat frequencies.

3. The apparatus of claim 2, further comprising a control loop coupled to the frequency selector and the first semiconductor laser to maintain the RF output at a selected frequency.

4. The apparatus of claim 3 wherein the control loop comprises a divider coupled to the frequency selector, the divider to receive the RF output and to output a divided-down RF output.

5. The apparatus of claim 4 wherein the control loop comprises an error circuit coupled to the divider, the error circuit to output an error signal that indicates the difference between the divided-down signal and a reference signal.

6. The apparatus of claim 5 wherein the control loop comprises a wavelength controller to adjust a wavelength output of the first semiconductor laser in response to the error signal.

7. The apparatus of claim 1 wherein the first and second semiconductor lasers are packaged in the same package.

8. The apparatus of claim 7 wherein the first and second semiconductor lasers are integrated on the same semiconductor die.

9. The apparatus of claim 8 wherein the first semiconductor laser includes a first Vertical Cavity Surface Emitting Laser (VCSEL) and the second semiconductor laser includes a second VCSEL.

10. The apparatus of claim 1 wherein at least one of the two or more beat frequencies are between approximately 0 and 100 Gigahertz.

11. The apparatus of claim 1 wherein the optical outputs of the first and second semiconductor lasers are directed to the detector by plastic reflectors.

12. A method, comprising:
generating beat frequencies by mixing the outputs of a first semiconductor laser and a second semiconductor laser;
selecting a beat frequency from the beat frequencies;
outputting the beat frequency as the RF source output; and
maintaining a frequency of the RF source output using a control loop.

13. The method 12 wherein maintaining the frequency of the RF output using the control loop comprises:
dividing the RF output to generate a divided-down signal;
computing a frequency error between the divided down signal and a reference signal; and
adjusting the output wavelength of the first semiconductor laser in response to the frequency error.

14. The method 12, further comprising tuning the RF output to a new RF output.

15. The method of claim 14 wherein tuning the RF output to a new RF output includes loading a new divide factor into the divider.

16. The method of claim 12 wherein adjusting the output wavelength of the first semiconductor laser includes at least one of using temperature control or using current control.

17. A system, comprising:
a radio upconvert chain; and
an RF source coupled to the radio upconvert chain, the RF source comprising:
a first semiconductor laser and a second semiconductor laser;
a detector optically coupled to the first and second semiconductor lasers, wherein the detector to output two or more beat frequencies generated by mixing optical outputs of the first and second semiconductor lasers, wherein the two or more beat frequencies are electrical signals; and
a frequency selector coupled to the detector to receive the two or more beat frequencies and to output a Radio Frequency (RF) output selected from the received the two or more beat frequencies.

18. The system of claim 17, further comprising an antenna coupled to the radio upconvert chain.

19. The system of claim 18, further comprising a second radio upconvert chain coupled to the radio upconvert chain, the second radio upconvert chain coupled to a low RF source.

20. The system of claim 18, further comprising a processor coupled to the radio upconvert chain.
